(19) United States
(12) Patent Application Publication
(10) Pub. No.: US 2005/0057752 A1
(43) Pub. Date: Mar. 17, 2005

(54) Method of detecting attracting force between substrates, and near-field exposure method and apparatus

(75) Inventors: Yasuhisa Inao, Kawasaki-shi (JP); Tomohiro Yamada, Yokohama-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 10/911,697

(22) Filed: Aug. 5, 2004

(30) Foreign Application Priority Data
Aug. 8, 2003 (JP) 290736/2003(PAT.

(51) Int. Cl. G01B 11/00; G03F 9/00; G03B 27/42

(52) U.S. Cl. 356/400; 430/5; 355/53

(57) ABSTRACT

Disclosed is a method of detecting an attraction force between substrates, and a near-field exposure method and apparatus, wherein, in the attraction force detecting method, an elastically deformable first substrate is intimately contacted to a second substrate which is not elastically deformable as compared with the first substrate and, when the first and second substrates so contacted are separated from each other, an attraction force acting between the first and second substrates is detected. Specifically, the includes at least one of (i) a step for detecting an attraction force acting between the first and second substrates on the basis of a difference between (a) a physical quantity necessary for intimately contacting the first substrate to the second substrate and (b) a physical quantity necessary for separating the first substrate from the second substrate, and (ii) a step of detecting an attraction force acting between the first and second substrates on the basis of an amount of deformation of the first substrate relative to the second substrate.

### FIELD OF THE INVENTION AND RELATED ART

This invention relates to a method of detecting an attraction force between substrates and to a near-field exposure method and a near-field exposure apparatus. More particularly, the invention concerns near-field exposure method and apparatus which is particularly effective to prevent breakage of an exposure mask in a manufacturing process of integrated circuits or liquid crystal displays (LCD), for example.

Because of recent needs for reduction in size and thickness of electronic instruments, miniaturization of semiconductor devices to be mounted in the electronic instruments has been required more and more.

For example, as regards the design rule for a pattern of a mask or reticle, a line-and-space (L&S) pattern of 130 nm is going to be produced through mass-production, and it will become much smaller soon. Generally, projection exposure apparatuses used recently prevalently have an illumination optical system for illuminating a mask with light from a light source, and a projection optical system disposed between the mask and an object to be exposed.

In such projection exposure apparatuses, generally it is said that the resolution limit is approximately at the wavelength of a light source used. Even if an excimer laser is used, it is difficult for a projection exposure apparatus to produce a pattern of 0.10 μm or less. Additionally, even if there is a light source having a shorter wavelength, the optical material (i.e., lens glass material) used in a projection optical system could not transmit such short wavelength, and, because the pattern could not be projected on an object to be exposed, the exposure could not be accomplished.

On the other hand, as a measure for enabling microprocessing of 0.1 μm or narrower, an exposure apparatus using a structure of a near-field optical microscope (scanning near-field optical microscope: SNOM), has been proposed. As an example of such exposure apparatus, U.S. Pat. No. 6,171,730 proposes a method and apparatus in which a mask being elastically deformable in a direction of a normal to the mask surface is intimately contacted to a resist and, by use of near field light leaking or seeping from a fine-opening pattern of a size not greater than 100 nm formed on the mask surface, local exposure that exceeds the light wavelength limit is performed to an object to be exposed. The method and apparatus disclosed in the aforementioned U.S. patent is very useful and it makes a large contribution to the technical field to which the present invention pertains.

As a feature of this method, the near field light leaking from a small opening is locally present in a range of distance of about the wavelength of light incident on the opening. Therefore, the distance between the opening and the object to be exposed must be kept not longer than the wavelength of light, more preferably, not longer than 100 nm, and contact exposure should be done. To this end, an elastically deformable mask is used as an exposure mask and, through flexure of the exposure mask to waviness or the like of a substrate, the mask can follow the substrate.

In the exposure method based on near field light as described above, the exposure mask and the resist are intimately contacted to each other. As a result, an attraction force may act between the exposure mask and the resist. Also, since the exposure mask used in this method is a mask of elastic material so that it can follow the substrate, when the exposure mask is separated or torn from the resist, a force might be applied to the exposure mask and, in some cases, it is possible that the mask is broken due to this attraction force.

In case the exposure mask is broken during the exposure process, it results in faults in a wafer or glass substrate to be produced and, in turn, it causes a decrease of yield. The reason is as follows.

First, when the exposure mask is broken, fragments of the exposure mask are scattered over the resist. If foreign particles such as mask fragments are present on the resist, it leads to a cause for adhesion of foreign particles that interfere with subsequent exposure process and other treatments. Furthermore, this necessitates additional works such as removing exposure mask fragments from the exposure apparatus and loading a fresh exposure mask. It causes shortened operation time of the apparatus and decreased throughput of it. Second, even after breakage of the exposure mask, the broken exposure mask may be moved to a subsequent exposure position for the resist, such that fragments of the exposure mask may be scattered over theses portions of the resist. It leads to a cause for adhesion of foreign particles that interfere with subsequent exposure process and other treatments to be made to the object to be processed such as a substrate. Thus, the yield of wafers or glass substrates to be produced may be decreased thereby.

In consideration of these inconveniences, in an exposure method based on near field light, it is desired to predict breakage of an exposure mask and, at least, to stop the operation of the exposure apparatus just after the breakage.

### SUMMARY OF THE INVENTION

It is accordingly an object of the present invention to provide a method of detecting an attraction force between substrates, a near-field exposure method or a near-field exposure apparatus, by which an attraction force between substrates can be detected, by which breakage of an exposure mask during an exposure process can be avoided, and by which yield of wafers or glass substrates as well as throughput can be improved.

The present invention can provide a method of detecting an attraction force between substrates, a near-field exposure method and a near-field exposure apparatus, arranged to be described below.

Specifically, in accordance with an aspect of the present invention, there is provided a method of detecting an attraction force between substrates, wherein an elastically deformable first substrate is intimately contacted to a second substrate which is not elastically deformable as compared with the first substrate and, when the first and second substrates so contacted are separated from each other, an attraction force acting between the first and second substrates is detected, characterized in that: said method comprises at least one of (i) a step for detecting an attraction force acting between the first and second substrates on the basis of a difference between (a) a physical quantity necessary for intimately contacting the first substrate to the second substrate and (b) a physical quantity necessary for separating the first substrate from the second substrate, and (ii) a step of detecting an attraction force acting between the first and second substrates on the basis of an amount of deformation of the first substrate relative to the second substrate.

In one preferred form of this aspect of the present invention, the physical quantity necessary for intimately contacting the first substrate to the second substrate and/or the physical quantity necessary for separating the first substrate from the second substrate, is a pressure for deforming the first substrate.

The amount of deformation of the first substrate relative to the second substrate may be detected on the basis of a displacement of a light receiving position, of light projected to the first object and reflected thereby, upon a light receiving portion that receives the reflected light.

In accordance with another aspect of the present invention, there is provided a near-field exposure method wherein an exposure mask is deformed and is intimately contacted to a resist substrate and then it is separated from the resist substrate, and wherein exposure is carried out on the basis of near field leaking from a small opening formed in the exposure mask, characterized by: a step of detecting an attraction force acting between the exposure mask and the resist substrate, when the exposure mask is separated from the resist substrate.

In one preferred form of this aspect of the present invention, the detection of attraction force is carried out in accordance with an attraction force detecting method as recited above.

The attraction force detecting step may include a step of stopping deformation of the exposure mask when a value of the attraction force as detected in accordance with the attraction force detecting method exceeds a predetermined value.

In accordance with a further aspect of the present invention, there is provided a near-field exposure apparatus for performing exposure on the basis of near field light, said apparatus having a pressure adjustable container and an exposure mask formed with fine openings, wherein the exposure mask is deformed by adjusting a pressure inside the pressure adjustable container so that it is intimately contacted to a resist substrate and then the exposure mask is separated from the resist substrate, characterized by: attraction force detecting means for detecting an attraction force acting between the exposure mask and the resist substrate, when the exposure mask is separated from the resist substrate.

In one preferred form of this aspect of the present invention, the attraction force detecting means is arranged to detect the attraction force on the basis of at least one of (i) a change in the pressure inside the pressure adjustable container to be used for deforming the exposure mask to cause intimate contact of or separation of the exposure mask to or from the resist substrate, and (ii) an amount of deformation of the exposure mask when the exposure masks is deformed to cause intimate contact of or separation of the exposure mask to or from the resist substrate.

The structure for detecting the attraction force on the basis of the amount of deformation of the exposure mask may be based on an optical displacement sensor by which the deformation can be detected from a displacement of a light receiving position, of light projected to a first object and reflected thereby, upon a light receiving portion that receives the reflected light.

The exposure apparatus may be arranged so that deformation of the exposure mask is stopped when a value of the attraction force as detected in accordance with said attraction force detecting means exceeds a predetermined value.

In accordance with the present invention, the attraction force between substrates can be detected, this being particularly effective to prevent breakage of an exposure mask during an exposure process. Thus, the present invention can provide a near-field exposure method and apparatus by which the yield and throughput for wafers and glass substrates, for example, can be improved.

Particularly, when the attracting force detecting means of the present invention is applied to a near-field exposure method and apparatus and if, at the separation of the exposure mask and the resist, the pressure at start of tearing is lower than a preset value, or if a largest angular change is larger than a preset value, use of the exposure mask can be interrupted. This effectively avoids breakage of the exposure mask during operation of the exposure apparatus. As a result of this, there is no possibility that fragments of the exposure mask are scattered over the resist or inside the exposure apparatus, and the yield of wafers or glass substrates to be produced can be increased. Furthermore, the necessity of complicated works for removing fragments inside the exposure apparatus, caused by breakage of the exposure mask, can be removed or reduced, and the throughput of the apparatus can also be improved.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIGS. 1A and 1B are schematic views, respectively, of an exposure mask according to an embodiment of the present invention.

FIG. 2 is a schematic view of an exposure apparatus having a sensor in accordance with an embodiment of the present invention.

FIG. 3 is a schematic view, illustrating changes of an exposure mask being intimately contacted to a resist and changes of a reflection light spot position upon a light receiving device, for explaining an embodiment of the present invention.

FIG. 4 is a schematic view, illustrating changes of an exposure mask being separated from a resist and changes of a reflection light spot position upon a light receiving device, for explaining an embodiment of the present invention.

FIG. 5 is a graph, showing an angular change due to deformation of an exposure mask, caused by an applied pressure, for explaining an embodiment of the present invention.

FIG. 6 is a schematic view of the structure of an exposure apparatus according to an embodiment of the present invention.

FIG. 7 is a graph, showing changes in angle of an exposure mask caused by an applied pressure, of an exposure mask in the first time use, in an embodiment of the present invention.

FIG. 8 is a graph, showing changes in angle of an exposure mask caused by an applied pressure, of an exposure mask in the twenty-thousandth time use, in an embodiment of the present invention.

FIG. 9 is a schematic view, showing the relation among an exposure mask, a light source and a light receiving portion, in an embodiment of the present invention.

FIG. 10 is a graph, showing changes in an output of a PSD (semiconductor position detector) caused due to changes inside a pressure adjustable container, the output changes being converted into angular changes.

### DESCRIPTION OF THE PREFERRED EMBODIMENTS

Preferred embodiments of the present invention will now be described with reference to the attached drawings.

First, an embodiment of detecting means for detecting an attraction force acting between an exposure mask and an object to be exposed, in accordance with the present invention will be described.

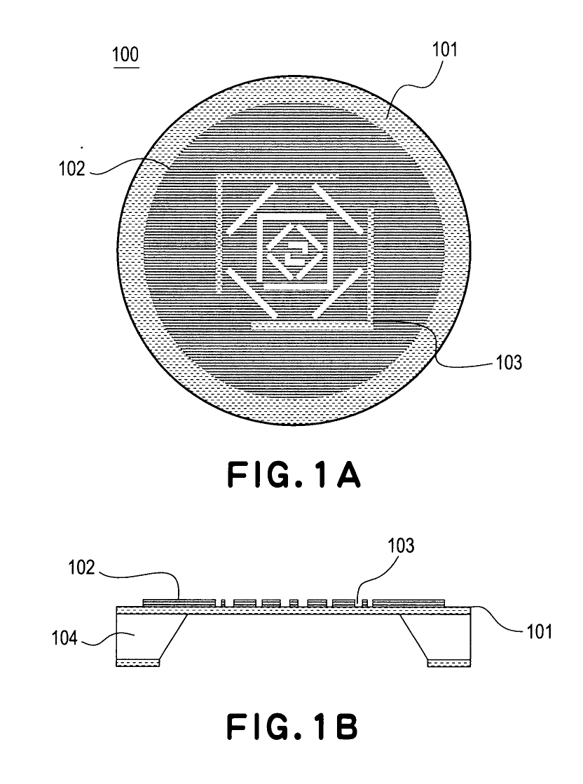

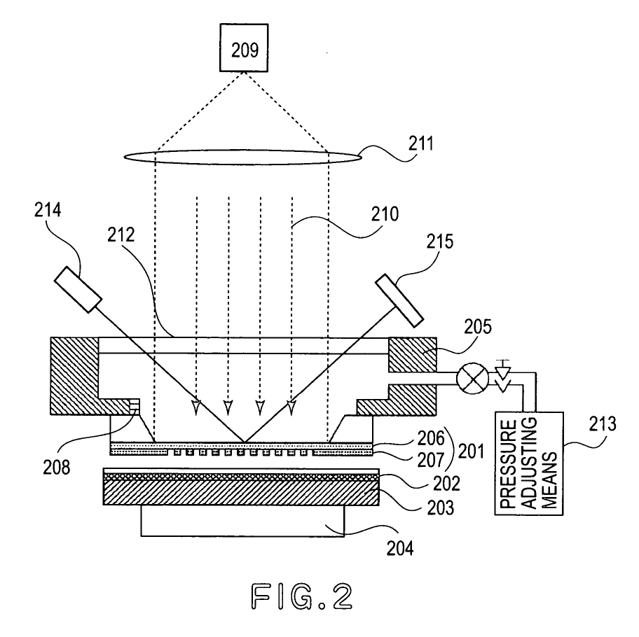

FIGS. 1A and 1B illustrate the structure of an exposure mask which is the subject of breakage prediction to be performed in accordance with a breakage predicting method of the present invention. FIG. 2 shows the structure of an exposure apparatus arranged to predict breakage of an exposure mask in accordance with the breakage predicting method of the present invention.

Referring to FIGS. 1A and 1B, an exposure mask 100 of the present invention will be explained.

FIGS. 1A and 1B shows an exposure mask which is used in the exposure apparatus shown in FIG. 2, wherein FIG. 1A illustrates the front face side of the mask, and FIG. 1B is a sectional view thereof. Here, in this specification, the wording “front face” refers to the surface on which a light blocking film is provided, while the wording “rear face” refers to the surface at an opposite side.

The exposure mask 100 in FIGS. 1A and 1B comprises a mask supporting member 104, a mask base material 101, and a light blocking film 102. The light blocking film 102 is formed on the mask base material 101, and small openings 103 are formed in the light blocking film 102, in a desired pattern. The mask base material 101 is made of an elastic material, and it is provided as a thin film.

The exposure mask 100 is disposed in a pressure adjustable container of a near-field exposure apparatus shown in FIG. 2, with the rear face of the exposure mask facing thereto. Pressure adjustment is then performed to the mask, to thereby adjust flexure or deflection of it.

Referring to the near-field exposure apparatus shown in FIG. 2, the near-field exposure operation based on the near field light and using an exposure mask described above, will be explained.

In FIG. 2, as an object to be exposed, there is a resist 202 formed on the surface of a substrate 203. Hereinafter, they will be referred also to as “resist/substrate (202/203). The resist/substrate (202/203) is mounted on a stage 204 and, by moving the stage 204, relative positional alignment of the substrate 203 relative to the exposure mask 201, with respect to two-dimensional directions along the mask surface, is carried out. Subsequently, the stage 204 is moved in a direction of a normal to the mask surface, so that the exposure mask 201 and the resist 202 on the substrate 203 are intimately contacted to each other so that, throughout the whole surface, the clearance between the mask 201 surface and the resist 202 surface is maintained at 100 nm or less.

Thereafter, exposure light 210 emitted from an exposure light source 209 and transformed by a collimator lens 211 into parallel light, passes a glass window 212 and is introduced into the pressure adjustable container 205. The thus introduced exposure light irradiates the exposure mask 201, from its rear face (upper side in FIG. 2), such that, with the near field leaking from a fine-opening pattern formed in the light blocking film 207 on the mask base material, at the front face of the exposure mask 201, the resist 202 is exposed.

Next, referring to FIG. 2, how to bring the exposure mask and the resist/substrate into intimate contact with each other will be described in detail. If the front face of the exposure mask 201 and the resist 202 surface on the substrate 203 are perfectly flat, they can be closely contacted to each other throughout the whole surface. Practically, however, there is surface irregularity or waviness on the mask surface or the resist/substrate surface. Thus, only by approximating them to each other and contacting them to each other, the result would be mixed distribution of closely contacted portions and non-closely contacted portions.

In consideration of this, a pressure is applied to the exposure mask from the rear face side of it to the front face side of it, to cause flexure in the exposure mask due to elastic deformation thereof, so that the mask is pressed against the resist/substrate 202/203. By this, the thin film portion can be closely contacted, throughout the whole surface.

As an example of such pressure applying method, as shown in FIG. 2, the exposure mask 201 is placed so that the front face thereof faces outwardly of the pressure adjustable container 205 while the rear face of the mask faces inside the pressure adjustable container 205. By using pressure adjusting means 213 such as a pump, for example, a high-pressure gas is introduced into the pressure adjustable container 205, so that the inside pressure of the container 205 becomes higher than the outside atmospheric pressure.

Here, the high-pressure gas is introduced into the pressure adjustable container 205 from the pressure adjusting means 213, to increase the pressure inside the container 205, such that the front face of the exposure mask 201 and the resist 202 surface on the substrate 203 are brought into close contact with each other, throughout the whole surface.

If the pressure is applied in the manner described above, due to the Pascal's principle, the repulsive force acting on between the front face of the near field mask 201 and the resist 202 surface on the substrate 203 becomes uniform. As a result, there is no possibility that a large force is locally applied to the exposure mask 201 or the resist 202 surface on the substrate. Therefore, it effectively prevents local breakage of the exposure mask 201, the substrate 203 or the resist 202.

In this example, for intimate contact of the exposure mask 201 and the resist/substrate 202/203, the rear face of the exposure mask is placed inside the pressure adjusting container 205 and, on the basis of a pressure difference with the outside atmospheric pressure which is lower than the inside pressure of the container 205, a pressure is applied to the exposure mask 201 from the rear face side to the front face side of it. However, as an inverse structure, the front face of a near field mask and a resist/substrate may be placed inside a reduced-pressure container and, on the basis of a pressure difference with the outside atmospheric pressure which is higher than the inside pressure of the container, so that a pressure may be applied to the near field mask from its rear face side to its front face side. Anyway, a pressure difference may be defined so that the pressure is higher at the rear face side as compared with that at the front face side of the near field mask.

Next, referring to FIG. 2, an optical type displacement sensor used in an embodiment of the present invention will be described. In this embodiment, the optical displacement sensor is incorporated into an exposure apparatus based on near field light, for detecting intimate contact between an exposure mask and an object to be exposed.

In FIG. 2, the optical displacement sensor comprises a light source 214 and a light receiving portion 215. Light emitted from the light source 214 is incident on a thin film portion of the exposure mask 201, i.e., the object of detection. The light source 214 emits the light so that reflection light of the incident light impinges on the light receiving portion 215.

If the exposure mask 201 (object of detection) shifts, the position of a light spot on the light receiving portion 215 changes in accordance with the displacement. Such positional change can be read as a displacement of the mask.

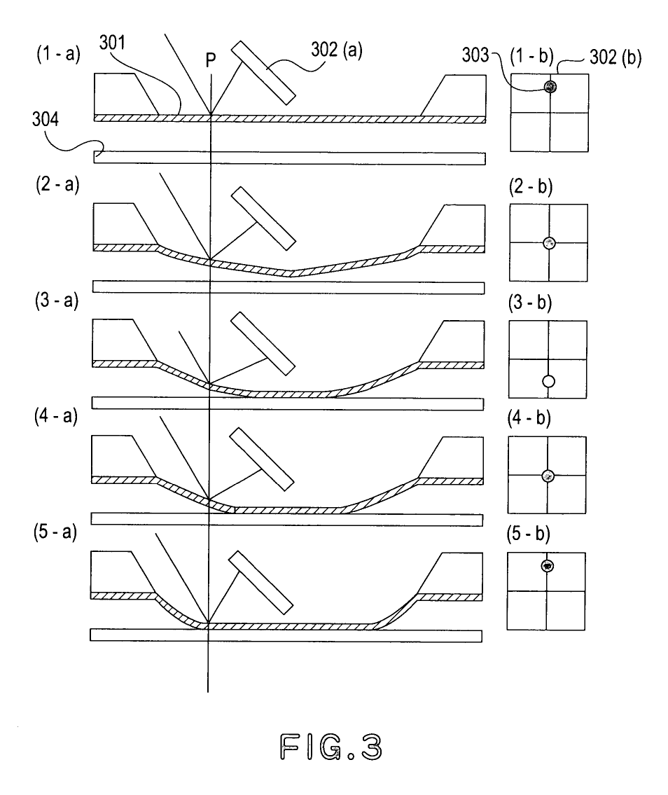

Next, referring to FIG. 3, the position of spot of reflection light which is changeable with deformation of the exposure mask will be explained in detail.

In FIG. 3, stages (*-a) (* is any one of numerals 1-5) illustrate changes in the thin film, and stages (*-b) (again, * is any one of numerals 1-5) illustrate changes in the spot position 303 of reflection light upon the light receiving portion, corresponding to the stages (*-a), respectively.

In this example, the rear face of the exposure mask faces inside the pressure adjustable container, and the pressure inside the container (pressure at the rear face side of the mask) is made higher than the front face side pressure, so that the thin film portion of the exposure mask is flexed. Square frames in FIG. 3 depict the light receiving portion 302(b) when the light receiving portion 302(a) is seen from the light entrance side. Also, a straight line with a character P denotes the position to be irradiated with light emitted from a light source.

Referring to the stages (1-a) to (5-a) in FIG. 3, the process of intimate contact of the exposure mask will be explained in detail.

At stage (1-a) in FIG. 3, the exposure mask is not yet flexed. Now, the position of the light source, the light irradiating position P on the exposure mask, and position of the light receiving portion 302 are adjusted so that the spot 303 of the reflection light is placed at the position shown in stage (1-b) of FIG. 3. Subsequently, as the exposure mask starts being flexed, there occurs a change in an order of stage (2-a), stage (3-a), stage (4-a) and stage (5-a) of FIG. 3. At stage (2-a) of FIG. 3, the mask is just before intimately contacted to the object to be exposed and, regarding the irradiation position P, since the exposure mask is slightly tilted as compared with the initial position thereof, the position of reflection light spot shifts slightly downwardly as shown in stage (2-b) of FIG. 3, as compared with stage (1-b).

After this, the central portion of the exposure mask begins close contact with the object to be exposed. At this time, the tilt of the exposure mask increases, and the spot position of the reflection light upon the light receiving portion deviates downwardly from the irradiation spot position P. Thereafter, the closely contacted portion increases and, at the state of stage (3-a) of FIG. 3, the tilt becomes largest and the spot position is lowered most.

As the exposure mask is flexed furthermore to extend the closely contacted portion, as seen in stage (4-a) of FIG. 3, the tilt of the exposure mask at the irradiation spot position P gradually decreases and the reflection spot position shifts upwardly as seen in stage (4-b) of FIG. 3.

As the closely contacted portion is extended furthermore and, at the irradiation spot position P, the exposure mask is closely contacted to the object to be exposed, as seen in stage (5-a) of FIG. 3, the tilt of the exposure mask becomes equal to the tilt of the object to be exposed, that is, the same tilt as at the initial position of the exposure mask. Also, the reflection spot position shifts upwardly to substantially the same position, as seen in stage (5-b) of FIG. 3.

In the manner described above, during a period from start of flexure of the exposure mask to close contact at the position P, the reflection light spot 303 makes one reciprocal motion along the light receiving portion 302. As the reflection light spot 303 returns to substantially the same position as the initial position thereof, detection of close contact between the exposure mask and the object to be exposed is enabled.

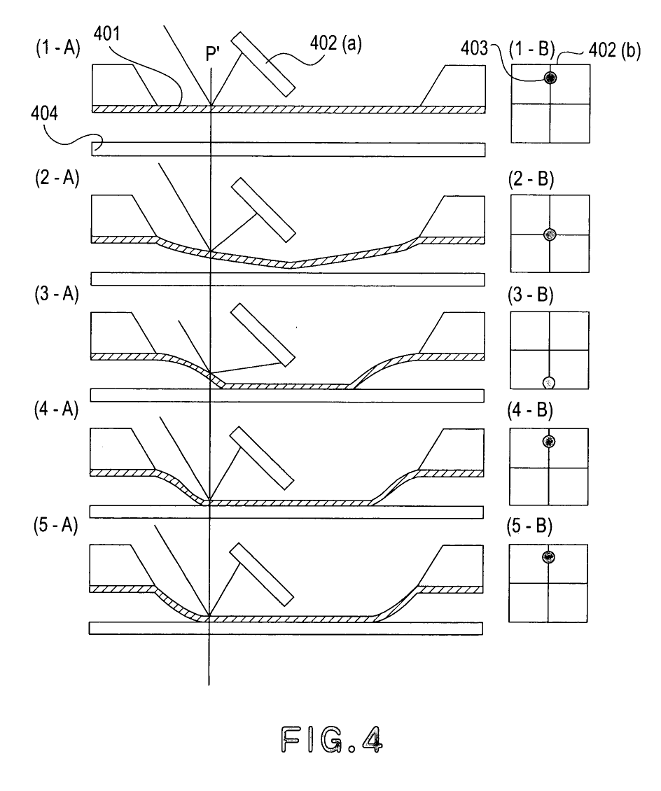

Referring now to FIG. 4, the position of the reflection light spot as the exposure mask is going to be separated from the resist, after completion of exposure made through intimate contact of the exposure mask and the object to be exposed, will be described in detail.

FIG. 4 is similar to FIG. 3, and stages (*-A) (* is any one of numerals 1-5) illustrate changes in the thin film, and stages (*-B) (again, * is any one of numerals 1-5) illustrate changes in the spot position 403 of reflection light upon the light receiving portion, corresponding to the stages (*-A), respectively. These stages illustrate, in an order from stage (5-A) to stage (1-A), the states from close contact of the exposure mask and the resist to complete separation of them.

The manner of change of the thin film during separation differs from the manner of change of the thin film in the close contacting procedure, and the difference appears when an attraction force acts between the exposure mask and the resist. More specifically, if any attraction force is not present between the thin film and the resist, the thin film turns back along the trace thereof during the close contacting procedure. If on the other hand there is an attraction force, the changes are such as illustrated in FIG. 4.

Next, the spot position of reflection light which changes with deformation of the mask will be explained, in an order from stage (5-A) to stage (1-A) of FIG. 4. Here, it should be noted that the pressure is even between stage (*) in FIG. 3 and stage (*) in FIG. 4.

In stage (5-A) of FIG. 4, the thin film and the resist are closely contacted to each other. It is assumed that, at this stage, there is an attraction force acting between the thin film and the resist. After this, as seen in stage (4-A) of FIG. 4, the pressure is lowered to enable separation of the thin film from the resist. However, there is an attraction force acting between the thin film and the resist and, since the pressure is insufficient to overcome such attraction force, a change occurs only in the non-close contact region of the thin film. There occurs no change in the thin film portion at the irradiation spot position P′. Here, as regards the irradiation spot position P′, a portion where the thin film and the resist are closely contacted to each other is chosen. Thus, as seen in stage (4-B) of FIG. 4, the position of the reflection light spot does not shift from the reflection spot position in stage (5-B) of FIG. 4.

As the pressure is lowered furthermore thereafter, the portion at the irradiation spot position P′ begins to be torn off. At this moment, since the central portion is yet peeled, the changing speed of the tilt of the thin film at the irradiation spot position P′ becomes faster (stage (3-A) of FIG. 4) and the reflection light spot 403 shifts largely downwardly (stage (3-B) of FIG. 4). Thereafter, if the pressure is reduced furthermore, the force of separating the thin film becomes stronger than the attraction force, and the whole surface of the thin film portion is separated. Thus, it has the same deformation amount as in stage (2-a) of FIG. 3 (stage (2-A) of FIG. 4). As the pressure is reduced furthermore and the pressure difference between the front face and the rear face of the thin film is removed, the thin film turns back to the state before flexure (stage (1-A) of FIG. 4).

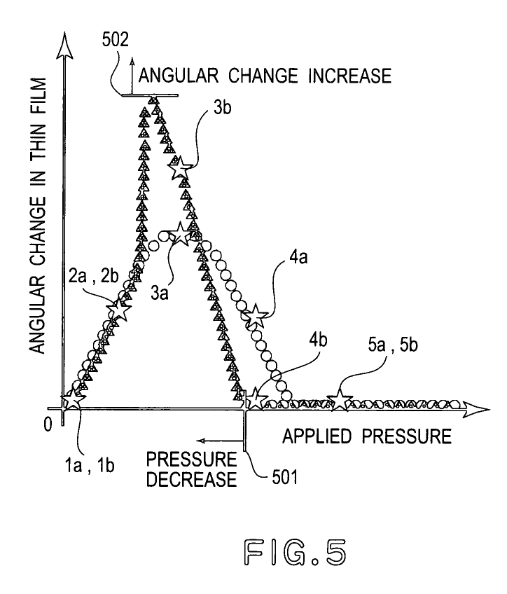

As described sequentially, due to the presence of an attraction force between the thin film and the resist, the trace of deformation of the thin film during close contact shown in FIG. 3 and the trace of deformation of the thin film during separation shown in FIG. 4 differs from each other. If the reflection light spot position at the light receiving portion is detected continuously and the results are converted into angular changes of the thin film, a graph such as shown in FIG. 5 is obtainable. In FIG. 5, small circles depict angular changes during close contact, and small triangles depict angular changes during separation. It is seen from the graph that, as the attraction force increases, the separation staring pressure 501 decreases. That is, unless the pressure inside the pressure adjustable container is reduced furthermore, the thin film is not separated from the resist and the amount of deformation of the thin film becomes larger. Thus, the largest angular change 502 increases. The position at (#a) in FIG. 5 corresponds to (#) in FIG. 3 (# is any one of numerals 1-5) and the position at (#b) corresponds to (#) of FIG. 4 (again, # is any one of numerals 1-5).

If the attraction force between the thin film and the resist is large, the required force necessary for separation of the thin film and the resist becomes large. This means a large load to the exposure mask and it leads to an enlarged deformation amount of the exposure mask. As a result, the exposure mask may be broken as it could not bear the load. It should be noted that there is a tendency that the attraction force becomes stronger in dependence upon the times of close contact of the exposure mask to the resist.

In the present invention, a particular note has been made to the attraction force between an exposure mask formed with a thin film and a resist, such as described above, and an increase of the attraction force is read from a change in the force necessary for separating the exposure mask from the resist. Also, a bearable load of the exposure mask due to deformation thereof is set and, if it is discriminated that the attraction force exceeds the set load, use of that exposure mask is interrupted in response to it. More specifically, while the pressure level or the largest angular change whereat the thin film begins separation is monitored, if the pressure level becomes lower than the set level or the largest angular change becomes larger than the set value, it is concluded that the exposure mask is in the state that it might be possibly broken at any time. Thus, the exposure mask is replaced by another. Here, the set value may be different in accordance with the material, shape or structure, for example, of the mask to be used. It may be determined by calculation, or it may be determined on the basis of the results of breakage experiments made to similar masks.

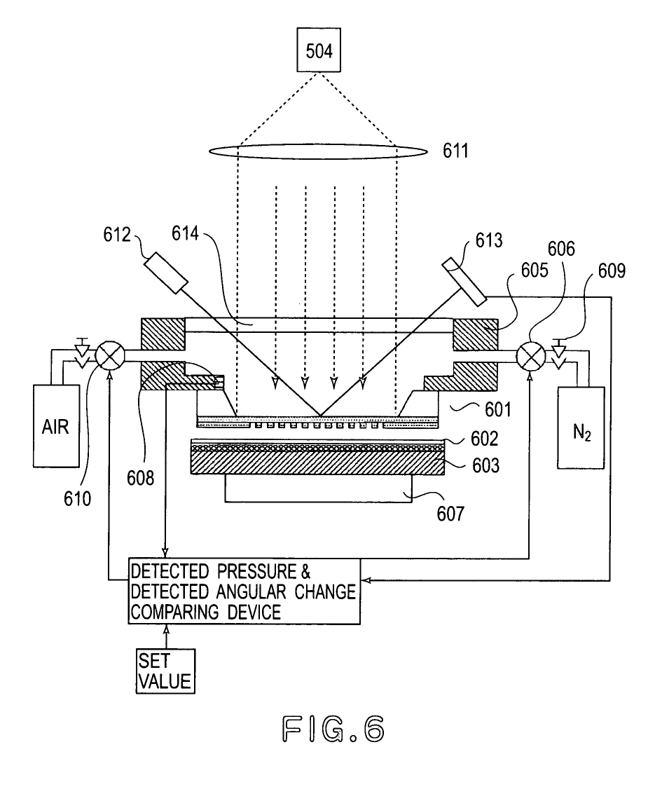

FIG. 6 illustrates the structure of a near-field exposure apparatus according to an embodiment of the present invention, into which the attracting force detecting means for an exposure mask according to the above-described embodiment is incorporated.

In FIG. 6, denoted at 601 is an exposure mask and denoted at 602 is a photoresist being applied to a substrate 603, the resist being the object to be exposed.

In the present example, the clearance between the front face of the exposure mask 601, having its rear face placed inside a pressure adjustable container 605, and the surface of the photoresist 602 was fixed at about 100 μm. The thin film portion of the exposure mask used there had a size of 10 mm×10 mm and a thickness of 1 μm. Regarding this exposure mask, it is experimentally known that the mask is broken when the pressure inside the pressure adjustable container 605, with which the exposure mask and the resist begin to separate from each other at the position of 3 mm from the center, becomes approximately equal to 3 kPa, or when the largest angular change of the thin film of the exposure mask 601 becomes equal to 1.3 degree. For this reason, in this example, the set value for the pressure to be used for prediction of breakage was 3 kPa and the set value for the angular change of the thin film was 1.1 degree.

While fixing the clearance between the exposure mask 601 and the photoresist, the exposure mask 601 is flexed so that it is closely contacted to the photoresist 602. To this end, and in order to supply nitrogen into the pressure adjustable container 605 to make the pressure thereof higher than the pressure outside the closed container, an electromagnetic valve 606 was opened and a nitrogen gas was fed into the pressure adjusting container 605. Here, a pressure sensor 608 provided inside the pressure adjusting container 605 was monitored, and the flow rate of nitrogen was controlled by a flow-rate adjusting device 609 so that it flowed at a pressurizing rate of 100 Pa/sec.

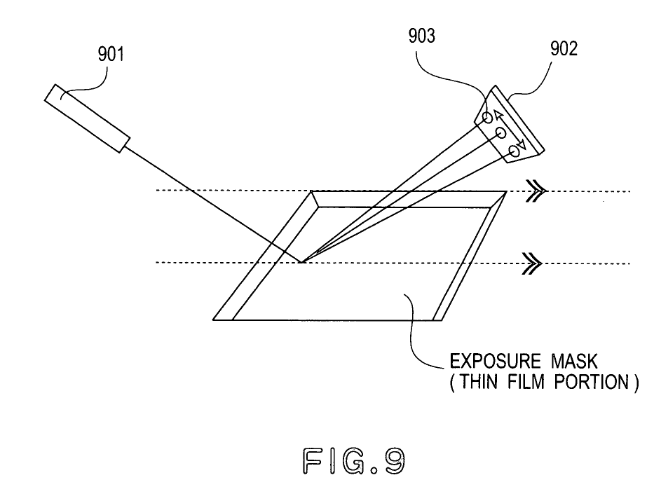

Here, as shown in FIG. 6, laser light LD of a semiconductor laser 612 having a wavelength 630 nm, from the outside of the closed container and being collimated into a beam diameter of 100 μm, was projected onto a region of the thin film portion of the exposure mask, at a distance of 3 mm from its center. Reflection light from it was received by a PSD (semiconductor position detector) 613, i.e., the light receiving portion provided outside the pressure adjusting container 605. Here, the laser beam was projected with the beam optical axis was held in parallel to the frame of the square shape of 10 mm×10 mm, defining the thin film, as shown in FIG. 9.

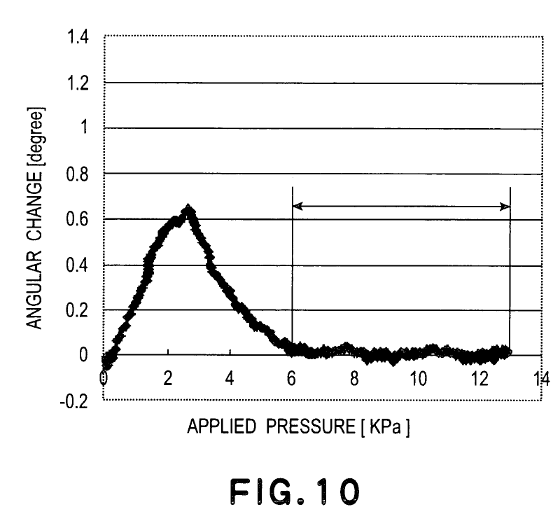

During changes of the inside pressure of the pressure adjusting container 605 at a rate of 100 Pa/sec., the thin film portion of the exposure mask 601 was flexed gradually. With the flexure of the exposure mask 601, the spot position on the PSD 613, receiving the reflection light, shifts and, in response to it, the voltage output of the PSD 613 changes. The graph of FIG. 10 illustrates the results as the values of changes in the output of PSD 613 caused by changes in the pressure are converted into angular changes. In the drawing, if the value of angular change (degree) taken on the axis of ordinate is large, it means that the position of the reflection light spot is placed lower on the light receiving portion. The axis of abscissa shows the inside pressure of the pressure adjusting container 605. As the pressure application to the pressure adjustable container 605 begins, the value of angular change increases and, after crossing a certain pressure level, it decreases again and becomes substantially equal to the output at the time of 0 Pa. The value of angular change does not shift any more with further pressure application (see an arrow in the drawing). This means that the exposure mask and the photoresist are closely contacted to each other, as has been described with reference to the embodiment. From the values of angular change obtained by converting the outputs of the pressure sensor 608 and the PSD 613, close-contact discriminating and controlling means concludes the state, in which the value of angular change does not shift even by application of pressure, as being accomplishment of close contact between the exposure mask 601 and the photoresist 602, and it closes the electromagnetic valve 606 and interrupts the flow of nitrogen, supplied to apply pressure.

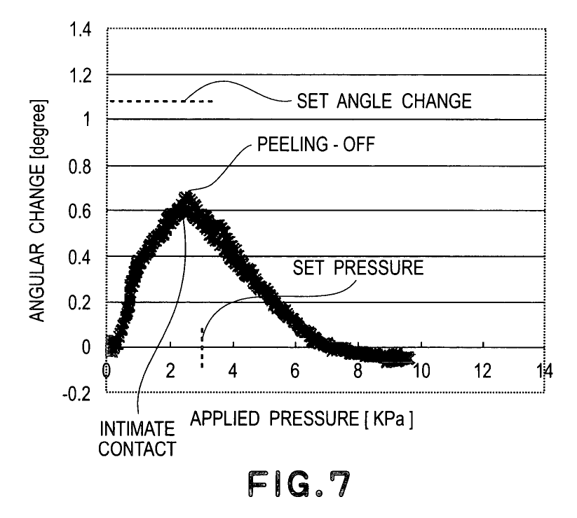

Thereafter, light of g-line (wavelength 436 nm) from an Hg lamp 604 is projected, whereby the photoresist is exposed. After the exposure, the electromagnetic valve 606 is opened, and nitrogen inside the pressure adjustable container 605 is discharged. Thus, the inside pressure of the container 605 is reduced to the atmospheric pressure level, and flexure of the exposure mask 601 is removed. The motion of the reflection light spot position on the PSD 613 as the flexure of the exposure mask 601 is removed, is similar to the motion in the close contact process, but it is in an opposite direction. The output voltage level of the PSD 613 once decreases and the value of angular change increases. At a certain pressure, it reaches a largest level and, after this, it decreases toward its initial position. As the value of angular change (output voltage level of PSD 613) turns back to its initial value, removal of flexure of the exposure mask can be detected. Angular changes with pressure from start of close contact to completion of separation, are shown in the graph of FIG. 7. It is seen from this graph that, for both of close contact and separation, the exposure mask shows similar angular changes.

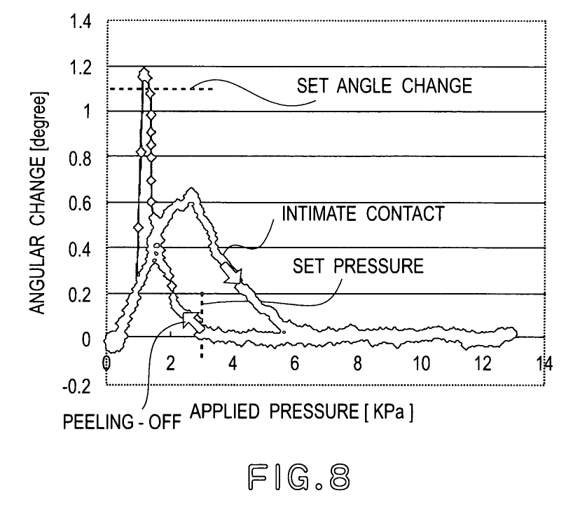

When similar operations were repeated thereafter by about 20,000 times, for separation of the exposure mask from the resist to be made after completion of the exposure process at that time, a graph of FIG. 8 was obtained. As it was confirmed that the separation stating pressure level was not greater than 3 kPa and the largest angular change exceeded 1.1 degree, use of that exposure mask was interrupted, and it was replaced by another.

The value of separation stating pressure and the value of largest angular change may preferably be monitored continuously through comparison with set values in a detected pressure and detected angular change comparing system.

For confirmation, exposure operation was continued while using the same exposure mask without replacement, and the result was that the mask was broken at about 20,300th use.

As described hereinbefore, by detecting a change of the reflection spot position on the light receiving portion, depending on the times of use, during separation of the exposure mask and the resist, breakage of the exposure mask can be predicted effectively.

While the invention has been described with reference to the structures disclosed herein, it is not confined to the details set forth and this application is intended to cover such modifications or changes as may come within the purposes of the improvements or the scope of the following claims.

This application claims priority from Japanese Patent Application No. 2003-290736 filed Aug. 8, 2003, for which is hereby incorporated by reference.

1-10. (Cancelled)

11. A method of detecting an attraction force between substrates, wherein an elastically deformable first substrate is intimately contacted to a second substrate, which is not elastically deformable as compared with the first substrate and, when the first and second substrates so contacted are separated from each other, an attraction force acting between the first and second substrates is detected, said method comprising:
at least one of (i) a step for detecting an attraction force acting between the first and second substrates on the basis of a difference between (a) a physical quantity necessary for intimately contacting the first substrate to the second substrate and (b) a physical quantity necessary for separating the first substrate from the second substrate, and (ii) a step of detecting an attraction force acting between the first and second substrates on the basis of an amount of deformation of the first substrate relative to the second substrate.

12. A method according to claim 11, wherein at least one of (i) the physical quantity necessary for intimately contacting the first substrate to the second substrate and (ii) the physical quantity necessary for separating the first substrate from the second substrate, is a pressure for deforming the first substrate.

13. A method according to claim 11, wherein the amount of deformation of the first substrate relative to the second substrate is detected on the basis of a displacement of a light receiving position, of light projected to the first object and reflected thereby, upon a light receiving portion that receives the reflected light.

14. A near-field exposure method wherein an exposure mask is deformed and is intimately contacted to a resist substrate and then it is separated from the resist substrate, and wherein exposure is carried out on the basis of a near-field leaking from a small opening formed in the exposure mask, said method comprising:
a step of detecting an attraction force acting between the exposure mask and the resist substrate, when the exposure mask is separated from the resist substrate.

15. A method according to claim 14, wherein the detection of the attraction force comprises at least one of (i) a step for detecting an attraction force acting between the exposure mask and the resist substrate on the basis of a difference between (a) a physical quantity necessary for intimately contacting the exposure mask to the resist substrate and (b) a physical quantity necessary for separating the exposure mask from the resist substrate, and (ii) a step of detecting an attraction force acting between the exposure mask and the resist substrate on the basis of an amount of deformation of the exposure mask relative to the resist substrate.

16. A method according to claim 15, wherein at least one of (i) the physical quantity necessary for intimately contacting the exposure mask to the resist substrate and (ii) the physical quantity necessary for separating the exposure mask from the resist substrate, is a pressure for deforming the first substrate.

17. A method according to claim 15, wherein the amount of deformation of the exposure mask relative to the resist substrate is detected on the basis of a displacement of a light receiving position, of light projected to the exposure mask and reflected thereby, upon a light receiving portion that receives the reflected light.

18. A method according to claim 15, wherein the attraction force detecting step includes a step of stopping deformation of the exposure mask when a value of the attraction force as detected in accordance with the attraction force detecting method exceeds a predetermined value.

19. A method according to claim 16, wherein the attraction force detecting step includes a step of stopping deformation of the exposure mask when a value of the attraction force as detected in accordance with the attraction force detecting method exceeds a predetermined value.

20. A method according to claim 17, wherein the attraction force detecting step includes a step of stopping deformation of the exposure mask when a value of the attraction force as detected in accordance with the attraction force detecting method exceeds a predetermined value.

21. A near-field exposure apparatus for performing exposure on the basis of near-field light, said apparatus comprising:
a pressure adjustable container;
an exposure mask formed with fine openings, wherein the exposure mask is deformed by adjusting a pressure inside the pressure adjustable container so that it is intimately contacted to a resist substrate and then the exposure mask is separated from the resist substrate; and
attraction force detecting means for detecting an attraction force acting between the exposure mask and the resist substrate, when the exposure mask is separated from the resist substrate.

22. An apparatus according to claim 21, wherein said attraction force detecting means is arranged to detect the attraction force on the basis of at least one of (i) a change in the pressure inside the pressure adjustable container to be used for deforming the exposure mask to cause intimate contact of or separation of the exposure mask to or from the resist substrate, and (ii) an amount of deformation of the exposure mask when the exposure mask is deformed to cause intimate contact of or separation of the exposure mask to or from the resist substrate.

23. An apparatus according to claim 22, wherein the structure for detecting the attraction force on the basis of the amount of deformation of the exposure mask is based on an optical displacement sensor by which the deformation can be detected from a displacement of a light receiving position, of light projected to a first object and reflected thereby, upon a light receiving portion that receives the reflected light.

24. An apparatus according to claim 21, wherein said apparatus is arranged so that deformation of the exposure mask is stopped when a value of the attraction force as detected in accordance with said attraction force detecting means exceeds a predetermined value.

25. An apparatus according to claim 22, wherein said apparatus is arranged so that deformation of the exposure mask is stopped when a value of the attraction force as detected in accordance with said attraction force detecting means exceeds a predetermined value.

26. An apparatus according to claim 23, wherein said apparatus is arranged so that deformation of the exposure mask is stopped when a value of the attraction force as detected in accordance with said attraction force detecting means exceeds a predetermined value.
